(19) United States
(12) Patent Application Publication
(10) Pub. No.: US 2026/0112421 A1
(43) Pub. Date: Apr. 23, 2026

(54) MEMORY CONTROLLER, STORAGE DEVICE AND METHOD OF OPERATING THE SAME

(71) Applicant: Samsung Electronics Co., Ltd., Suwon-si (KR)

(72) Inventors: Su Chang Jeon, Suwon-si (KR); Su-Yong Kim, Suwon-si (KR); Jung-Ho Song, Suwon-si (KR); Jung-Yun Yun, Suwon-si (KR)

(21) Appl. No.: 19/294,481

(22) Filed: Aug. 8, 2025

(30) Foreign Application Priority Data
Oct. 18, 2024 (KR) 10-2024-0143313

(51) Int. Cl. G11C 16/26; G11C 16/08; G11C 29/12

(52) U.S. Cl. CPC G11C 16/26; G11C 16/08; G11C 29/12005; G11C 2029/1202

(57) ABSTRACT

Provided is a storage device including a memory device including a memory block including a select transistor group connected to a special wordline, and a memory controller configured to identify a trigger time corresponding to the select transistor group, the trigger time being based on a degradation level of the select transistor group, and based on the trigger time elapsing, control the memory device to perform a program operation, the program operation comprising adjusting a threshold voltage of at least one of a plurality of select transistors included in the select transistor group.

### CROSS-REFERENCE TO RELATED APPLICATION

This application claims the benefit of Korean Patent Application No. 10-2024-0143313, filed on Oct. 18, 2024, in the Korean Intellectual Property Office, the entirety of which is incorporated herein by reference.

### BACKGROUND

A storage device is a device that stores data. The storage device may include a memory device and a memory controller. The memory device may include a plurality of storage areas. The memory device may include select transistors such as a string select transistor (SST) and a ground select transistor (GST). A select transistor can control access to a specific storage area by activating or inactivating that storage area. If the select transistor deteriorates due to program/erase cycles, temperature, etc., access to specific storage areas may become inaccessible, resulting in data loss. Measures to prevent this are required.

### SUMMARY

Aspects of the present disclosure provide memory controllers, storage devices, and methods of operating the same by which data reliability can be improved.

According to some implementations of the present disclosure, there is provided a storage device including a memory device including a memory block, wherein the memory block comprises a select transistor group connected to a special wordline, and a memory controller configured to identify a trigger time corresponding to the select transistor group, wherein the trigger time is based on a degradation level of the select transistor group and, based on the trigger time elapsing, control the memory device to perform a program operation, wherein the program operation comprises adjusting a threshold voltage of at least one of a plurality of select transistors included in the select transistor group.

According to some implementations of the present disclosure, there is provided a method of operating a storage device including a memory block, wherein the memory block comprises a select transistor group connected to a special wordline, the method including identifying a trigger time corresponding to the select transistor group, wherein the trigger time is based on a degradation level of the select transistor group, and based on the trigger time elapsing, performing a program operation to adjust a threshold voltage of at least one of a plurality of select transistors included in the select transistor group.

According to some implementations of the present disclosure, there is provided a memory controller including a buffer memory configured to store information, and a processor configured to store a trigger time in the buffer memory, wherein the trigger time is based on a degradation level for a select transistor group of a memory block included in the memory device, and based on the trigger time elapsing, control the memory device to perform a program operation, wherein the program operation comprises adjusting a threshold voltage of at least one of a plurality of select transistors included in the select transistor group.

Additional features and characteristics will be set forth in part in the description which follows and, in part, will be apparent from the description, or may be learned by practice of the disclosure.

According to some implementations, it is possible to provide a memory controller, a storage device and a method of operating the same by which data reliability is improved. According to some implementations, it is possible to prevent or minimize deterioration of select transistors in advance. According to some implementations, it is possible to minimize data loss due to deterioration of the select transistors. According to some implementations, it is possible to improve the stability and extend the life of memory blocks.

Effects of the present disclosure are not limited to those described above, and other effects may be made apparent to those skilled in the art from the following description.

### BRIEF DESCRIPTION OF THE FIGURES

These and other aspects, features, and advantages provided herein will become apparent from the following description, taken in conjunction with the accompanying drawings of which:

FIG. 1 is a block diagram illustrating an example of a storage device;

FIG. 2 is a diagram illustrating an example of a memory block;

FIG. 3 is a flowchart illustrating an example of a method of operating a storage device;

FIG. 4 is a flowchart illustrating an example of a method of operating a storage device;

FIG. 5A to FIG. 5C are plots illustrating the threshold voltage of a select transistor;

FIG. 6 illustrates an example of mapping information of degradation level and trigger time;

FIG. 7 illustrates an example of trigger time information;

FIG. 8 is a diagram illustrating an example of a memory controller; and

FIG. 9 is a diagram illustrating an example of a memory device.

### DETAILED DESCRIPTION

Throughout the specification, when a part is described as “comprising or including” a component, it does not exclude another component but may further include another component unless otherwise stated. Furthermore, terms such as “. . . unit,” “. . . group,” and “. . . module” described in the specification mean a unit that processes at least one function or operation, which may be implemented as hardware, software, or a combination thereof.

Hereinafter, various examples will be described in detail with reference to the accompanying drawings. However, the scope of the present disclosure may be implemented in multiple different forms and is not limited to the specific examples described herein.

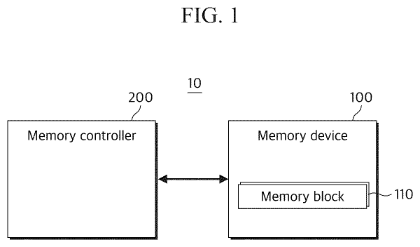

FIG. 1 is a block diagram illustrating an example of a storage device according to some implementations of the present disclosure. Referring to FIG. 1, a storage device 10 may include a memory device 100 and a memory controller 200. For example, the storage device 10 may be implemented as various types of electronic devices such as a solid state drive (SSD), an embedded multi media card (eMMC), a universal flash storage (UFS), a secure digital (SD) card (for example, a SD high capacity (SDHC) card, a SD eXtended Capacity (SDXC) card, a microSD card, a microSDHC card, microSDXC card, etc.), a CompactFlash (CF) card, XQD, CFast, CFexpress, a universal serial bus (USB) flash drive, a network attached storage (NAS) and a direct attached storage (DAS). However, the type of the storage device 10 is not limited to the examples described above and may be implemented in various modified and other forms.

The memory controller 200 may communicate with the memory device 100. For example, the memory device 100 and the memory controller 200 may communicate with each other according to various types of communication standards such as toggle double data rate (DDR), separate command address (SCA) protocol, and open NAND flash interface (ONFI).

The memory controller 200 may control the memory device 100. In some implementations, the memory controller 200 may transmit a command to the memory device 100 to control the memory device 100. When the command is received, the memory device 100 may perform operations corresponding to the command. In some implementations, the memory controller 200 may transmit an address representing a specific storage area of the memory device 100 along with the command to the memory device 100. When the command and the address are received, the memory device 100 may perform an operation corresponding to the command on the storage area corresponding to the address.

The command may control the operation of the memory device 100. For example, the type of command may include at least one of various types such as a program command that controls the execution of a program operation for storing data, a read command that controls the execution of a read operation for outputting the stored data and an erase command that controls the erase operation for deleting stored data. The address may refer to a specific storage area. For example, the type of address may include at least one of a block address indicating a specific memory block, a row address indicating a specific row (for example, wordline or special wordline) and a column address indicating a specific column (for example, bitline, etc.).

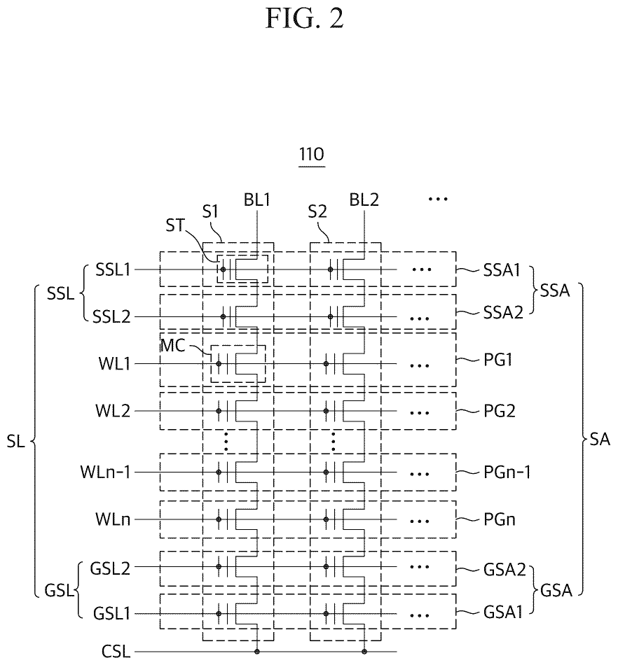

The memory device 100 may store data. The memory device 100 may include one or more memory blocks 110. The memory block 110 may include a plurality of pages. Each page may include a plurality of memory cells. A memory cell may be a non-volatile memory device. A page is a storage area that serves as a unit of a program operation (or a write operation) for storing data and a read operation for reading data. The memory block 110 may be a storage area that serves as a unit of the erasure operation to delete data. The memory block 110 will be described in more detail with reference to FIG. 2.

FIG. 2 is a diagram illustrating an example of a memory block. Referring to FIG. 1 and FIG. 2, the memory block 110 may include a plurality of pages PG1 to PGn. Each of the plurality of pages PG1 to PGn may include a plurality of memory cells MC. Each page may be linked to a corresponding wordline among a plurality of wordlines WL1 to Wln. The plurality of wordlines WL1 to Wln or the plurality of pages PG1 to PGn may be identified based on the row address. The plurality of memory cells MC within a single page may be connected to the same wordline. The plurality of memory cells MC within a single page may be connected to a plurality of bitlines (a bitline BL1 and a bitline BL2). The plurality of bitlines (the bitline BL1 and the bitline BL2) or the plurality of memory cells MC within a page may be identified according to the column address. Meanwhile, the number of the plurality of wordlines WL1 to Wln and the number of the plurality of bitlines (the bitline BL1 and the bitline BL2) may be implemented in various variations.

In some implementations, the memory cell MC may be a non-volatile memory device. For example, the memory cell MC may include a gate, a source, a drain, and a charge trap layer (CTL). A gate may be connected to one of the plurality of wordlines WL1 to WLn, and voltage may be applied through the connected wordline. The source and drain may be terminals through which the current flows. The CTL may be an insulating layer that confines charge (for example, a silicon insulating layer, etc.). The threshold voltage of the memory cell MC may be determined based on the charge stored in the CTL. For example, the higher the charge, the higher the threshold voltage may be. The memory cell MC may store data depending on the threshold voltage. For example, the memory cell MC may store data in various ways such as a single level cell (SLC) that stores 1 bit, a multi-level cell (MLC) that stores 2 bits, a triple-level cell (TLC) that stores 3 bits, and a quad-level cell (QLC) that stores 4 bits. For example, the memory cell MC may be implemented by changing the charge trap layer to a floating gate.

In some implementations, the memory block 110 may include a plurality of strings (a string S1 and a string S2). Each of the plurality of strings (the string S1 and the string S2) may include one end connected to one of a plurality of bitlines (the bitline BL1 and the bitline BL2) and another end connected to a source line CSL. The plurality of strings (the string S1 and the string S2) or the plurality of bitlines (the bitline BL1 and the bitline BL2) may be identified by column address. Each of the plurality of strings (the string S1 and the string S2) may include the plurality of memory cells MC connected in series.

The memory block 110 may include a plurality of select transistor groups SA. In some implementations, the memory block 110 may include a plurality of special wordlines SL. One select transistor group may be connected to one special wordline. The special wordline or the select transistor group may be identified according to the row address. Meanwhile, the special wordline may be referred to as a select line, and the select transistor group may be referred to as a select area.

In some implementations, the plurality of select transistor groups SA may include at least one string select transistor group SSA and at least one ground select transistor group GSA. One select transistor group may be one string select transistor group and one ground select transistor group. The plurality of special wordlines SL may include at least one string select line SSL and at least one ground select line GSL. One special wordline may be one string select line or one ground select line. The string select transistor group may be connected to the string select line. The ground select transistor group may be connected to the ground select line.

Each of the string select transistor group SSA and the ground select transistor group GSA may include a plurality of select transistors ST. In some implementations, access to a specific storage area may be enabled or disabled via the select transistor ST. The select transistor ST within the string select transistor group SSA may be referred to as a string select transistor, and the select transistor ST within the ground select transistor group GSA may be referred to as the ground select transistor. A plurality of string select transistors within a string select transistor group SSA may be identified according to a column address. The plurality of ground select transistors within the ground select transistor group GSA may be identified by the column address. The string select transistor may include a gate, a source and a drain connected to the string select line SSL. The ground select transistor may include a gate, a source and a drain connected to the ground select line GSL. In some implementations, each of the string select transistor and the ground select transistor may be a device having the same structure as the memory cell MC.

The number of string select transistor groups SSA and the number of ground select transistor groups GSA may vary in various implementations. For example, the string select transistor group SSA may include a first string select transistor group SSA1 and a second string select transistor group SSA2. The string select line SSL may include a first string select line SSL1 and a second string select line SSL2. The first string select transistor group SSA1 may be connected to the first string select line SSL1, and the second string select transistor group SSA2 may be connected to the second string select line SSL2. The number of string select transistor groups SSA may be equal to the number of string select lines SSL. Meanwhile, the ground select transistor group GSA includes a first ground select transistor group GSA1 and a second ground select transistor group GSA2, and the ground select line (GSL) may include a first ground select line (GSL1) and a second ground select line (GSL2). The first ground select transistor group (GSA1) is connected to the first ground select line (GSL1), and the second ground select transistor group (GSA2) may be connected to the first ground select line (GSL1). Here, the number of ground select transistor groups (GSA) may be equal to the number of ground select lines (GSL) It will be understood that the above-described transistor configuration is only an example, and the number of string select transistor groups SSA and the number of ground select transistor groups GSA differ from the foregoing in some implementations. In some implementations, the number of string select transistor groups SSA and the number of ground select transistor groups GSA may be different from one another.

In some implementations, each of the plurality of strings (the string S1 and the string S2) may include at least one string select transistor and at least one ground select transistor. The string select transistor and the ground select transistor may be located at either end of each string. For example, the string select transistor may be connected to one end of the series-connected plurality of memory cells MC, and the ground select transistor may be connected to the other end of the series-connected plurality of memory cells MC.

The string select transistor may be turned on or off depending on the voltage applied to the string select line SSL. For example, when a voltage higher than the threshold voltage of the string select transistor is applied to the string select line SSL, the string select transistor is in the “turn-on” state (or an active state) and the current may flow. When the string select transistor is in the “turn-on” state, strings (the string S1 and the string S2) including string select transistors may be electrically connected to bitlines (the bitline BL1 and the bitline BL2). As example, when a voltage lower than the threshold voltage of the string select transistor is applied to the string select line SSL, the string select transistor may be in the “turn-off” state (or an inactive state) and the current may be blocked. When the string select transistor is in the “turn-off” state, the strings (the string S1 and the string S2) including the string select transistors may be electrically isolated from the bitlines (the bitline BL1 and the bitline BL2).

The ground select transistor may be turned on or off depending on the voltage applied to the ground select line GSL. For example, if a voltage higher than the threshold voltage of ground select transistor is applied to the ground select line GSL, the ground select transistor is in the “turn-on” state (or the active state) and the current may flow. When the ground select transistor is in the “turn-on” state, the strings including ground select transistor (the string S1 and the string S2) may be electrically connected to the source line CSL. As example, when a voltage below the threshold voltage of the ground select transistor is applied to the ground select line GSL, the ground select transistor may be in the “turn-off” state (or the inactive state) and the current may be blocked. When the ground select transistor is in the “turn-off” state (or the inactive state), the strings including the ground select transistor (the string S1 and the string S2) may be electrically isolated from the source line CSL.

When both the string select transistor and the ground select transistor are in the “turn-on” state, it may be possible to access the memory cells MC within the strings (the string S1 and the string S2). When at least one of the string select transistor and the ground select transistor is in the “turn-off” state, access to the memory cells MC within the strings (the string S1 and the string S2) may be blocked. For example, when accessing the memory cell MC included in a specific memory block 110, by applying a voltage higher than the threshold voltage to the string select line SSL and the ground select line GSL of the memory block 110 selected by the address, the string select transistor and ground select transistor may be made to be in the “turn-on” state. Here, in the case of a memory block unselected by an address, the string select transistor and the ground select transistor may be made to be in the “turn-off” state by applying a voltage below the threshold voltage to the string select line SSL and the ground select line GSL of the unselected memory block.

For example, the select transistor ST may control access to a specific storage area by activating or inactivating (deactivating) the specific storage area. When the select transistor ST deteriorates due to program/erase cycle, temperature, etc., access to specific storage areas may become inaccessible, resulting in data loss.

According to some implementations of the present disclosure, data reliability may be improved in memory controllers and storage devices, such as the memory controller 200 and the storage device 10. For example, deterioration of the select transistor ST may be prevented or reduced in advance, and data loss may be reduced. Further, according to some implementations of the present disclosure, the stability of the memory block 110 may be improved, and the lifespan of the memory block 110 may be extended.

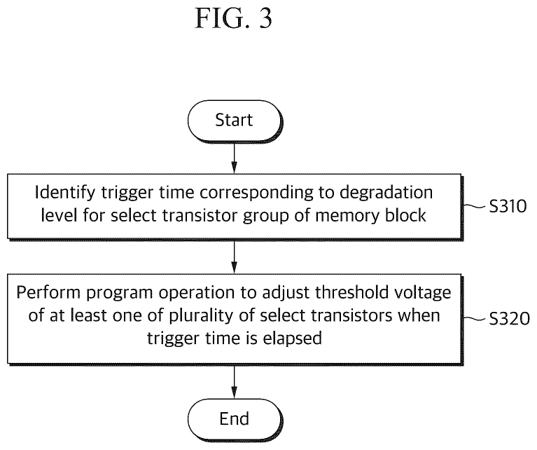

FIG. 3 is a flowchart for explaining an example of a method of operating a storage device according to some implementations of the present disclosure.

Referring to FIG. 3, a method of operating the storage device 10 may include operation S310 that is identifying a trigger time corresponding to the degradation level for the select transistor group SA of the memory block 110. In some implementations, the storage device 10 may include the memory device 100 including the memory block 110 and the memory controller 200 that controls the memory device 100. The memory block 110 may include the select transistor group SA, and the select transistor group SA may include a plurality of select transistors ST connected to the special wordline SL. Operation S310 may be performed by the memory controller 200.

When the memory block 110 is selected as the target of a data-related operation by address, the plurality of select transistors ST included in the select transistor group SA of the memory block 110 may be in the “turn-on” state. When the memory block 110 is not selected, the plurality of select transistors ST included in the select transistor group SA of the memory block 110 may be in the “turn-off” state.

In some implementations, the degradation level may indicate the extent to which the physical characteristics of a specific select transistor group SA have deteriorated. For example, the degradation level may be a value based on the number of select transistors ST whose threshold voltage has changed among the plurality of select transistors ST included in the select transistor group SA.

In some implementations, the method of operating the storage device 10 may include performing a read operation by applying the read voltage to the special wordline SL. Here, the read operation is to identify the threshold voltage of the select transistor included in the select transistor group SA, and may be referred to as a test read operation. In some implementations, the method of operating the storage device 10 may include determining the degradation level based on the number of failed select transistors having a threshold voltage lower than the read voltage among the plurality of select transistors ST included in the select transistor group SA. For example, performing the read operation and determining the degradation level may be performed before operation S310 that is identifying a trigger time.

In some implementations, the trigger time may indicate the time to start a program operation for a specific select transistor group SA. For example, the trigger time may indicate the expected remaining life. For example, the select transistor group SA may operate normally during the remaining lifetime, and when the remaining life expires, the select transistor group SA may operate abnormally. In some implementations, the trigger time may be a waiting time until a program operation for the select transistor group SA is initiated, or a waiting time before transmitting a program command that controls the start of a program operation. In some implementations, the trigger time may be a time representing the remaining life or an operation cycle.

In some implementations, operation S310 of identifying a trigger time may include identifying a trigger time that corresponds to a degradation level using mapping information. For example, in the case of the select transistor group SA with a high degradation level, there may be a short period of time remaining in which normal operation is possible, and in the case of the select transistor group SA with a lower degradation level, there may be a long period of time left for normal operation. Taking these characteristics into account, the mapping information may be set in advance, in order to identify or indicate that the higher the degradation level, the smaller the trigger time. In some implementations, the trigger time may be stored in the buffer memory of the memory controller 200.

In some implementations, the select transistor group SA may include a first select transistor group and a second select transistor group. The first degradation level for the first select transistor group may be greater than the second degradation level for the second select transistor group. In this case, the first trigger time corresponding to the first degradation level for the first select transistor group may be smaller than the second trigger time corresponding to the second degradation level for the second select transistor group.

In some implementations, operation S310 of identifying a trigger time may include identifying the trigger time corresponding to the degradation level from the saved trigger time information. In some implementations, the trigger time information may include an address, a degradation level, a trigger time, and correlations thereof. The address may include at least one of a block address representing the memory block 110 and a row address representing the select transistor group SA or the select wordline SL. In some implementations, the trigger time information may be stored in the buffer memory of the memory controller 200. In some implementations, when the trigger time information is stored in the buffer memory, the degradation level of the trigger time information may be omitted.

The method of operating the storage device 10 may include operation S320 which is performing a program operation for adjusting the threshold voltage of at least one of the plurality of select transistors ST included in the select transistor group SA when the trigger time is elapsed. Operation S320 may be performed by the memory controller 200.

In some implementations, the method of operating the storage device 10 may include determining whether a trigger time is elapsed. For example, the method of operating the storage device 10 may include identifying whether the trigger time is elapsed from the timepoint the trigger time for the select transistor group SA is identified. As another example, the method of operating the storage device 10 may include identifying whether the trigger time is elapsed from the timepoint when the trigger time for the select transistor group SA is stored.

In some implementations, the program operation may include a program pulse operation and a program verification operation. The program pulse operation may be an operation to inject charge into the CTL or floating gate of the select transistor ST by applying a program voltage to the special wordline SL. The threshold voltage of the select transistor ST may increase depending on the program pulse operation. The program verification operation is performed after the program pulse operation, and may be an operation to identify whether the threshold voltage of the select transistor ST has reached the target value (for example, voltage for verification) by applying the voltage for verification to the special wordline SL. In the program verification operation, when the threshold voltage reaches the target value, the program operation for the select transistor group SA may be completed. In the program verification operation, when the threshold voltage does not reach the target value, the program operation for the select transistor group SA may be performed repeatedly.

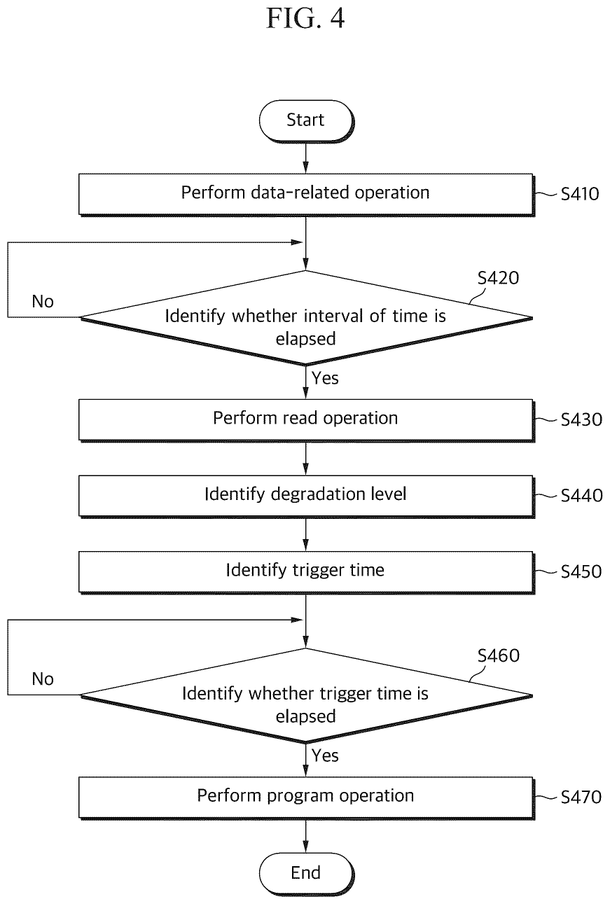

FIG. 4 is a flowchart illustrating an example of a method of operating a storage device according to some implementations of the present disclosure. Referring to FIG. 4, a method of operating the storage device 10 may include performing a data-related operation on the memory block 110 in operation S410. For example, the data-related operation on the memory block 110 may be one of a program operation to store data in the memory block 110 or a read operation to read data stored in the memory block 110. However, other data-related operations may instead or additionally be performed, such as an erase operation that deletes data stored in the memory block 110.

The method of operating the storage device 10 may include operation S420 that is identifying whether the interval of time is elapsed from the timepoint at which the data-related action has been completed. In some implementations, the interval of time may be an arbitrary variable time or a preset fixed time. For example, an arbitrary variable time may be one arbitrary value that is determined each time within a certain range (for example, between 1 ms and 100 s). The preset fixed time may be a fixed value, such as one specific value (for example, 1 ms, 2 ms, 5 ms, 1 s, 2 s, 5 s, etc.).

In some implementations, the method of operating the storage device 10 may include identifying whether the interval of time has elapsed using a clock counter included in the memory controller 200. The clock counter may increase (decrease) a counter value whenever a clock signal enters a specific state (for example, one of the first and second states), and identify that a specific amount of time has elapsed when the counter value reaches a target value. The clock signal may be a signal that transitions between a first state (for example, High state) and a second state (for example, Low state) at regular intervals. Here, the target value may be a value corresponding to an interval of time., The same signals and methods may be used to determine whether the trigger time is elapsed. In this case, the target value may be a value corresponding to the trigger time.

The method of operating the storage device 10 may include operation S430 in which, when the interval of time elapses from the timepoint at which the data-related operation is completed (S420, Yes), a read operation is performed by applying a read voltage to the special wordline SL. In the method of operating the storage device 10, when the interval of time is not elapsed (S420, No), operation may go back to the operation of identifying whether the interval of time is elapsed.

The method of operating the storage device 10 may include operation S440 that is identifying the degradation level based on the result of the read operation. In some implementations, operation S440 of identifying the degradation level may include identifying the degradation level based on the number of failed select transistors with the threshold voltage less than the read voltage, among the plurality of select transistors ST included in the select transistor group SA. In some implementations, the degradation level may be a value corresponding to the ratio of the number of the failed select transistors to the number of plurality of select transistors ST.

The method of operating the storage device 10 may include operation S450 that is identifying the trigger time corresponding to the degradation level. In some implementations, in the method of operating the storage device 10, operation S450 of identifying the trigger time may include determining the trigger time corresponding to the degradation level. For example, operation S450 of identifying the trigger time may include determining the trigger time corresponding to the degradation level according to the mapping information. For example, the mapping information may include, indicate, or provide a correlation in which the trigger time decreases as the degradation level increases. In some implementations, operation S450 of identifying the trigger time may include storing the trigger time corresponding to the degradation level. In some implementations, operation S450 of identifying the trigger time may include identifying the trigger time by loading the saved trigger time.

The method of operating the storage device 10 may include operation S460 that is identifying whether the trigger time is elapsed, e.g., when the trigger time is identified. In some implementations, the method of operating the storage device 10 may include identifying whether the trigger time is elapsed using the clock counter included in the memory controller 200.

The method of operating the storage device 10 may include operation S470 that is, when the trigger time is elapsed (S460, Yes), performing a program operation that applies the program voltage to the special wordline SL. In the method of operating the storage device 10, when the trigger time is not elapsed (S460, No), operations may go back to identifying whether the trigger time is elapsed.

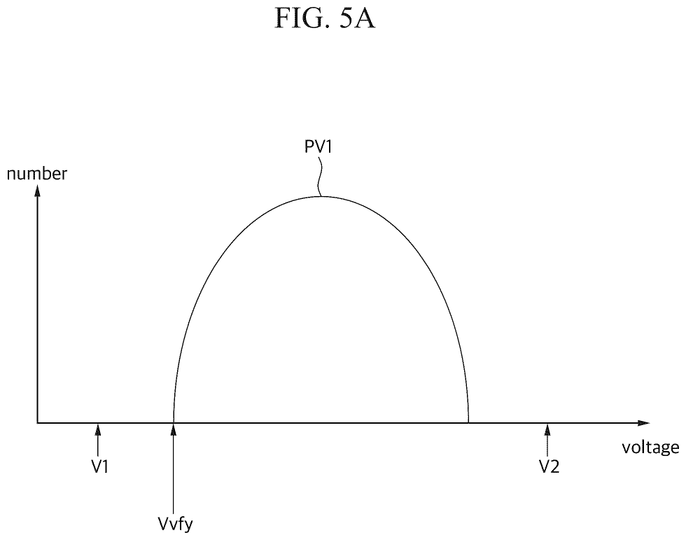

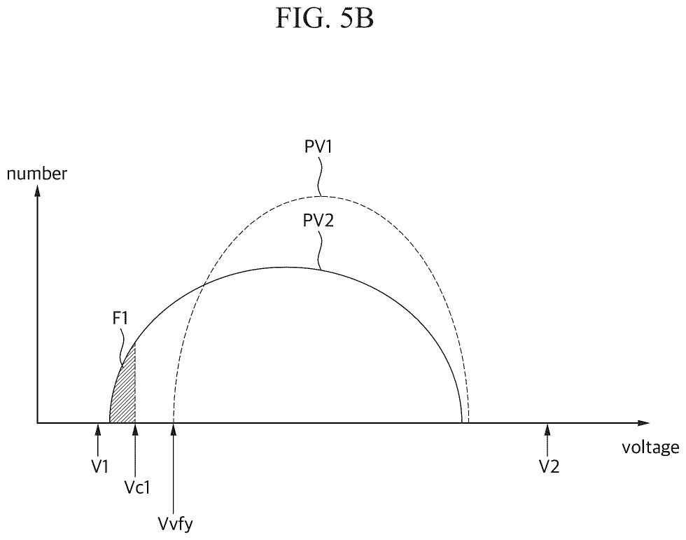

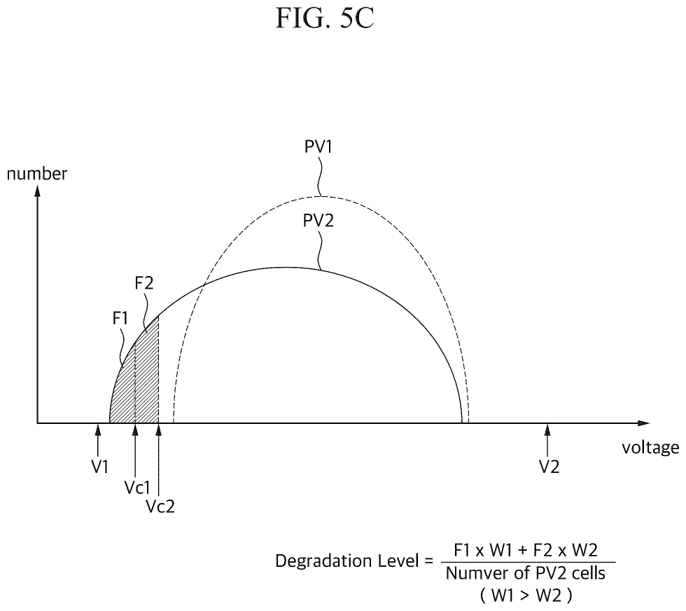

FIG. 5A to FIG. 5C are drawings illustrating the threshold voltage of a select transistor according to some implementations of the present disclosure.

Referring to FIG. 5A to FIG. 5C, the horizontal axis of the graph is the voltage or the threshold voltage, and the vertical axis of the graph represents the plurality of select transistors ST included in one select transistor group SA, and the number of select transistors ST with a specific threshold voltage. In some implementations, one special wordline SL may be connected to one select transistor group SA.

Referring to FIG. 5A, in the initial state, the plurality of select transistors ST may have a first threshold voltage state PV1, where PV1 illustrates a distribution of the threshold voltages. The initial state may indicate the state before deterioration occurs. For example, the initial state may be a state where the program/erase cycle is less than or equal to the reference value (for example, 0, 5, 10, etc.). As another example, the initial state may be a state in which power-on time is less than the reference value (for example, 30 seconds, 1 minute, 5 minutes, 10 minutes, etc.).

In some implementations, a program operation for the select transistor group SA including the plurality of select transistors ST may be performed using a voltage Vvfy for verification to have the first threshold voltage state PV1. For example, a program pulse operation may be performed, in which a program voltage is applied to the special wordline SL connected to the plurality of select transistors ST, and a program verification operation may be performed in which the voltage Vvfy for verification is applied to the special wordline SL and it is identified whether the threshold voltage of a plurality of select transistors ST is greater than or equal to the voltage Vvfy for verification. Until the threshold voltage of the plurality of select transistors ST becomes greater than or equal to the voltage Vvfy for verification, the program pulse operation and program verification operation may be performed repeatedly. For example, the plurality of select transistors ST may be programmed according to the SLC method.

In some implementations, when an operation is performed on the memory block 110 including the select transistor group SA, the select transistor group SA may be activated via a first voltage V1. If no operation is performed on the memory block 110, the select transistor group SA may be inactive via a second voltage V2.

Here, the first voltage V1 may be the voltage that is set to deactivate the select transistor group SA, and the second voltage V2 may be the voltage that is set to activate the select transistor group SA. For example, the first voltage V1 may be a voltage that is set to 0V, 2V, etc., and the second voltage V2 may be a voltage that is set to 4V, 6V, etc. The first voltage Vvfy for verification may be a voltage that is set to be greater than the first voltage V1 and less than the second voltage V2. Information about the first voltage V1, the second voltage V2 and the voltage Vvfy for verification may be stored inside the memory controller 200 or the memory device 100.

For example, when the first voltage V1, which is less than the threshold voltage of the select transistor ST, is applied to the special wordline SL, the select transistor ST connected to the special wordline SL may be in the inactive state (or the “turn-off” state). When the second voltage V2 exceeding the threshold voltage of the select transistor ST is applied to the special wordline SL, the select transistor ST connected to the special wordline SL may be in the active state (or the “turn-on” state).

The threshold voltage of the select transistor ST may deteriorate as the program/erase cycle increases after the initial state, or due to factors such as temperature.

Referring to FIG. 5B and FIG. 5C, the plurality of select transistors ST may have a second threshold voltage state (or distribution) PV2. In this case, the threshold voltage of a plurality of select transistors ST may be lowered from the first threshold voltage state PV1 to the second threshold voltage state PV2. For example, as degradation progresses, the difference (or margin) between the threshold voltage of the select transistor ST and the first voltage V1 decreases, and as the degradation becomes more severe, the threshold voltage of the select transistor ST may become less than the first voltage V1. In this case, when the first voltage V1 is applied, the connection of the bitline or source line is not cut off because the select transistor ST is activated, and interference may occur when performing a program operation or a read operation for an adjacent memory cell, which may lower the reliability of the data.

In some implementations, the memory controller 200 may control the memory device 100 to perform a read operation that is to apply a read voltage to the special wordline SL connected to the select transistor group SA. For example, the memory controller 200 may transmit the address corresponding to the read command and the special wordline SL to the memory device 100. The memory device 100 may perform a read operation by applying a read voltage to the special wordline SL according to the read command and the address.

In some implementations, the read voltage may be greater than the first voltage V1 that is configured to deactivate the select transistor group SA in a reference state (e.g., a non-degraded state, etc.). In some implementations, the read voltage may be less than the second voltage V2 that is configured to activate the select transistor group SA in the reference state. For example, the read voltage may include a first sub-read voltage Vc1. The first sub-read voltage Vc1 may be greater than the first voltage. The first sub-read voltage Vc1 may be less than the second voltage V2.

In some implementations, the memory device 100 may identify a failed select transistor having a threshold voltage lower than a read voltage among the plurality of select transistors ST included in the select transistor group SA by performing a read operation. The memory device 100 may transmit information about the fail state of the select transistor to the memory controller 200. In some implementations, the information about the failed select transistors may include the number of failed select transistors. In some implementations, information about the failed select transistor may further include the address of the failed select transistor.

In some implementations, the memory controller 200 may determine the degradation level based on the number of failed select transistors with a threshold voltage lower than the read voltage among the plurality of select transistors ST included in the select transistor group SA. For example, the memory controller 200 may determine the number of failed select transistors based on information about failed select transistors received from the memory device 100.

In some implementations, the degradation level may be a value corresponding to the ratio of the number of failed select transistors and the number of plurality of select transistors ST.

In some implementations, the memory device 100 may perform a read operation that is applying the first sub-read voltage Vc1 to the special wordline SL. In this case, the memory device 100 may identify the first number (F1) of select transistors ST having a threshold voltage lower than the first sub-read voltage Vc1.

For example, when the total number of select transistors ST included in the select transistor group SA is 1000 and when the first number (F1) of failed select transistors among the plurality of select transistors ST is 10, the memory controller 200 may divide the first number (F1) by the total number, and identify the degradation level for the select transistor group SA as a value of 0.01. Alternatively, the memory controller 200 may identify the degradation level for the select transistor group SA as a percentage of 10%. However, these representations are merely examples, and the degradation level may be implemented by various values.

Referring to FIG. 5C, the read voltage may include the first sub-read voltage Vc1 and a second sub-read voltage Vc2. The first sub-read voltage Vc1 may be greater than the first voltage V1. The second sub-read voltage Vc2 may be greater than the first sub-read voltage Vc1. The second sub-read voltage Vc2 may be less than the second voltage V2. The number of read voltages may be different in various implementations, e.g., may be one, two, or more than two.

In some implementations, the degradation level may be a value corresponding to a weighted sum of the first number (F1) of select transistors ST having a threshold voltage less than the first sub-read voltage Vc1 and the second number (F2) of select transistors ST having a threshold voltage greater than or equal to the first sub-read voltage Vc1 and less than the second sub-read voltage Vc2, among the plurality of select transistors ST.

In some implementations, the memory device 100 may perform a read operation by applying the first sub-read voltage Vc1 to the special wordline SL. In this case, the memory device 100 may identify the first number (F1) of select transistors ST having a threshold voltage lower than the first sub-read voltage Vc1. Further, the memory device 100 may perform a read operation by applying the second sub-read voltage Vc2 to the special wordline SL. In this case, the memory device 100 may identify the second number (F2) of select transistors ST having a threshold voltage greater than or equal to the first sub-read voltage Vc1 and less than or equal to the second sub-read voltage Vc2.

In some implementations, a first weight value W1 may be applied to the first number (F1), and a second weight value W2 may be applied to the second number (F2). In this case, the weighted sum may be the sum of the product of the first number (F1) and the first weight value W1 and the product of the second number (F2) and the second weight value W2. The first weight value W1 may be greater than the second weight value W2. For example, the second weight value W2 may be less than the first weight value W1. For example, a higher weight may be applied to select transistors with severe threshold voltage degradation. In some implementations, the value corresponding to the weighted sum may be the value obtained by dividing the weighted sum by the number of plurality of select transistors ST included in the select transistor group SA or a percentage value thereof. However, this calculation and value is an example, and the degradation level may be transformed into various values based on the weighted sum described above.

In some implementations, the read voltage may be the voltage Vvfy for verification applied during a program verification operation for the select transistor group SA, or less than the voltage Vvfy for verification. In some implementations, when the read voltage includes the first sub-read voltage Vc1, the first sub-read voltage Vc1 may be less than or equal to the voltage Vvfy for verification. In some implementations, when the read voltage includes the first sub-read voltage Vc1 and the second sub-read voltage Vc2, the second sub-read voltage Vc2 may be less than or equal to the voltage Vvfy for verification.

Accordingly, the trigger time corresponding to the degradation level may be identified before the select transistor ST begins to operate abnormally, and after the trigger time is elapsed, the threshold voltage of the select transistor ST may be adjusted. Thus, in some implementations, the reliability of data storage may be improved.

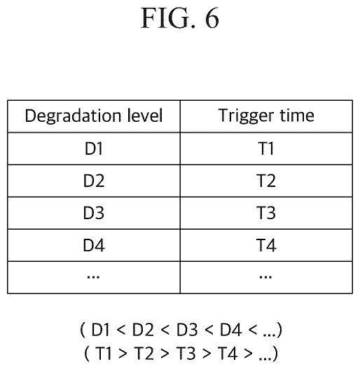

FIG. 6 illustrates an example of mapping information of degradation level and trigger time according to some implementations of the present disclosure. Referring to FIG. 6, when the degradation level for the select transistor group SA is identified, in some implementations, the memory controller 200 may identify a trigger time corresponding to the degradation level. In some implementations, the memory controller 200 may identify a trigger time corresponding to a degradation level based on mapping information including degradation levels and trigger times corresponding to each other. The memory controller 200 may store the trigger times for the select transistor group SA.

In some implementations, mapping information may include a plurality of degradation levels D1 to D4, a plurality of trigger times T1 to T4, and their correlations or associations. For example, in the mapping information, the first trigger time T1 may correspond to the first degradation level D1 and the second trigger time T2 may correspond to the second degradation level D2. When the degradation level for the select transistor group SA is the second degradation level D2, the memory controller 200 may identify the second trigger time T2 corresponding to the second degradation level D2 as the trigger time for the select transistor group SA according to the mapping information.

In some implementations, the mapping information may include or be based on a correlation that the trigger time decreases as the level of deterioration increases. The mapping information may be, but is not limited to, data in lookup table format. For example, the mapping information may be transformed into or represented by various data formats.

For example, the first degradation level D1, the second degradation level D2, the third degradation level D3, and the fourth degradation level D4 may have larger values in that order. The first trigger time T1, the second trigger time T2, the third trigger time T3, and the fourth trigger time T4 may have smaller values in that order. Among multiple degradation levels D1 to D4 in the mapping information, the fourth degradation level D4 with the largest value may correspond to the fourth trigger time T4 with the smallest value among the plurality of trigger times T1 to T4, and the third degradation level D3 with the next largest value may be corresponded to the third trigger time T3 with the next smallest value. In the same way, the degradation level and trigger time may have an inverse correlation. This takes into account the characteristic that the greater the degradation level, the shorter the remaining time for normal operation, and the smaller the degradation level, the longer the time remaining for normal operation.

In some implementations, the mapping information may include a correlation where a trigger time of 0 corresponds to a degradation level that is maximal (for example, 100%). For example, when the degradation level is 100%, the program operation may be performed immediately.

It will be understood that the above-described mapping information is only an example, and that the degradation levels and trigger times may be implemented in various ways within the scope of this disclosure, e.g., by modifying the above correlation according to various statistics or experiments.

In some implementations, the memory controller 200 may include a buffer memory. The buffer memory may store the mapping information.

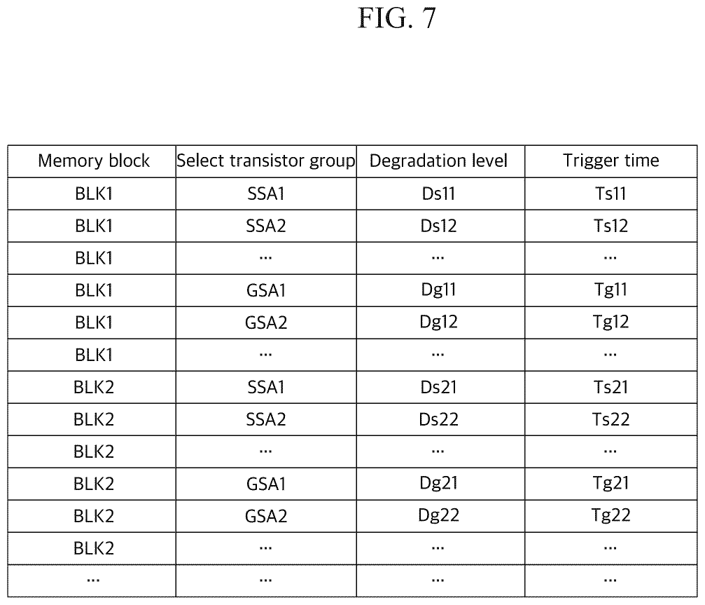

FIG. 7 is a drawing illustrating an example of trigger time information according to some implementations of the present disclosure. Referring to FIG. 7, when the degradation level for a specific select transistor group included in a specific memory block is identified, the memory controller 200 may identify the trigger time corresponding to the degradation level. In some implementations, the memory controller 200 may include a buffer memory. The memory controller 200 may store trigger time information regarding the trigger time in the buffer memory.

In some implementations, the trigger time information may include a correlation between a block address representing a specific memory block, a row address representing a specific select transistor group, and a trigger time. For example, a first trigger time Ts11 included in the trigger time information may indicate the trigger time for the first string select transistor group SSA1 included in a first memory block BLK1. In some implementations, the trigger time information may further include a corresponding degradation level. For example, a first degradation level Ds11 included in the trigger time information may indicate the degradation level for the first string select transistor group SSA1 included in the first memory block BLK1.

In some implementations, the memory controller 200 may determine the trigger time for each select transistor group through trigger time information. For example, when the first trigger time Ts11 is elapsed, the memory controller 200 may control the memory device 100 to perform a program operation which is adjusting the threshold voltage of at least one of the plurality of select transistors included in the first string select transistor group SSA1 of the first memory block BLK1.

In some implementations, when the trigger time is elapsed, the memory controller 200 may transmit a program command to control the execution of a program operation and an address corresponding to a select transistor group to the memory device 100. For example, when the first trigger time Ts11 is elapsed, the memory controller 200 may transmit a program command, a block address indicating the first memory block BLK1, and a row address indicating the first string select transistor group SSA1 to the memory device 100.

When a program command and an address are received, the memory device 100 may perform a program operation on a select transistor group corresponding to an address. In some implementations, a program operation may include applying the program voltage to the special wordline SL, applying the program allowance voltage to a bitline connected to a select transistor among the plurality of select transistors ST having a threshold voltage lower than the voltage for verification, and applying the program inhibit voltage to a bitline connected to a select transistor having a threshold voltage greater than the voltage for verification.

For example, a select transistor with a threshold voltage lower than the voltage for verification may, while applying the program voltage to the special wordline SL to increase the threshold voltage since the voltage for verification has not yet been reached, apply the program allowance voltage to its bitline. A select transistor with the threshold voltage greater than the voltage for verification has already reached the voltage for verification, and thus, in order to prevent the threshold voltage from rising, while the program voltage is being applied to the special wordline SL, the program inhibit voltage may be applied to the corresponding bitline. For example, the program allowance voltage may be set to 0V, etc., and the program inhibit voltage may be a voltage that is set to 4V, 6V, etc. For example, the memory device 100 may adjust the threshold voltage of a select transistor among a plurality of select transistors included in a select transistor group, the select transistor having a threshold voltage lower than the voltage for verification.

Here, the voltage for verification may be the same voltage as the voltage Vvfy for verification to create the first threshold voltage state PV1 of FIG. 5A. In some implementations, the voltage for verification may be transformed to a voltage greater than or less than the voltage Vvfy for verification to create the first threshold voltage state PV1 of FIG. 5A.

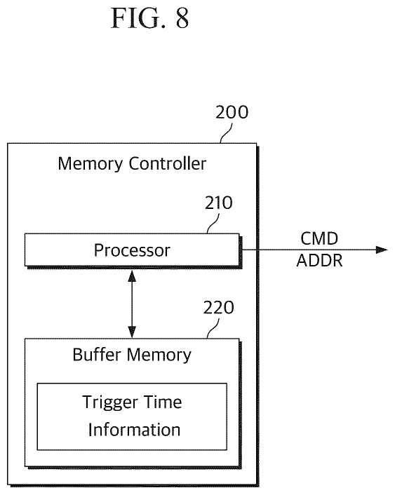

FIG. 8 is diagram illustrating an example of a memory controller according to some implementations of the present disclosure. Referring to FIG. 8, the memory controller 200 may include a processor 210 and a buffer memory 220. The buffer memory 220 may store various information. In some implementations, the buffer memory 220 may include various volatile memories such as dynamic random access memory (DRAM), static RAM (SRAM), and synchronous DRAM (SDRAM). In some implementations, the buffer memory 220 may include a non-volatile memory.

The buffer memory 220 may store trigger time information. The trigger time information may include an address and a trigger time. The address may include at least one of a block address and a row address. In some implementations, the trigger time information may further include the degradation level.

The processor 210 may control the overall operation of the memory controller 200. The processor 210 may execute programs or compute (or process) data. For example, the processor 210 may include at least one of a central processing unit (CPU), a digital signal processor (DSP), an application processing unit (APU), and a system on chip (SoC).

The processor 210 may generate various commands to control the memory device 100. For example, a command may include at least one of types such as a program command that controls the execution of a program operation for storing data, a read command that controls the execution of a read operation for outputting the stored data and an erase command that controls the erase operation for deleting stored data.

The processor 210 may identify the degradation level for the select transistor group of the memory block 110 included in the memory device 100. For example, the processor 210 may identify the degradation level for the select transistor group using information about the failed select transistor obtained as a result of performing a read operation on the select transistor group.

In some implementations, the processor 210 may control the memory device 100 to perform a read operation by applying a read voltage to a special wordline connected to a select transistor group. In some implementations, the processor 210 may determine a degradation level based on the number of failed select transistors. For example, the processor 210 may transmit an address and a read command corresponding to a select transistor group to the memory device 100. The memory device 100 may perform a read operation and transmit information about the fail state of the select transistor to the processor 210. The failed select transistor in the fail state may be a select transistor having a threshold voltage less than the read voltage among the plurality of select transistors included in the select transistor group.

In some implementations, when the interval of time elapses from the timepoint at which the data-related operation for the memory block 110 included in the memory device 100 is completed, the processor 210 may control the memory device 100 to perform the read operation by applying the read voltage to the special wordline connected to the select transistor group. Here, the interval of time may be an arbitrary variable time or a preset fixed time.

The processor 210 may identify the trigger time for a select transistor group based on the degradation level for the select transistor group. The processor 210 may store the trigger time for the select transistor group in the buffer memory 220.

When the trigger time is elapsed, the processor 210 may control the memory device 100 to perform a program operation by which adjusted is a threshold voltage of at least one of a plurality of select transistors included in a select transistor group.

In some implementations, when the trigger time is elapsed, the processor 210 may transmit a program command to control the execution of a program operation and an address corresponding to a select transistor group to the memory device 100.

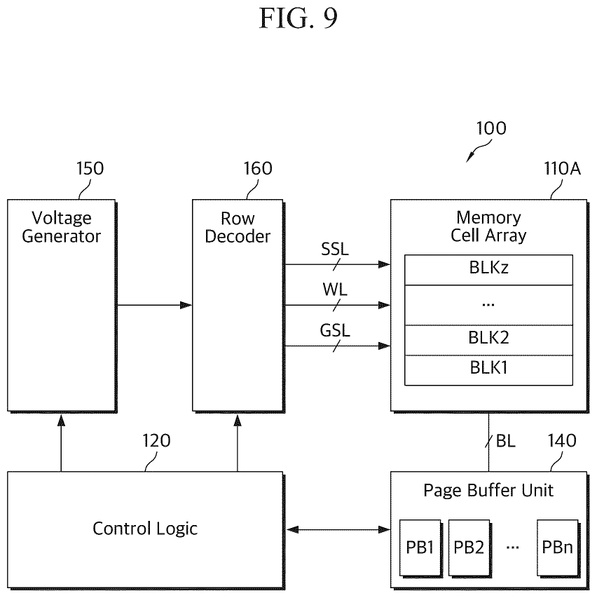

FIG. 9 is a diagram illustrating an example of a memory device according to some implementations of the present disclosure.

Referring to FIG. 9, the memory device 100 may include at least one of a memory cell array 110A, a control logic 120, a page buffer unit 140, a voltage generator 150, and a row decoder 160.

The memory cell array 110A may include a plurality of memory blocks BLK1 to BLKz. Each of the plurality of memory blocks BLK1 to BLKz may include a plurality of strings. Each of the plurality of strings may include a plurality of memory cells and a plurality of select transistors. Each plurality of strings may be connected to the page buffer unit 140 through its corresponding bitline BL. Each of the plurality of memory blocks BLK1 to BLKz may include a plurality of pages and a plurality of select transistors groups. Each of the plurality of pages may be connected to the row decoder 160 through a corresponding wordline WL. Each of a plurality of select transistors groups may be connected to the row decoder 160 via a corresponding special wordline. The special wordline may include the string select line SSL and the ground select line GSL. The description of the memory block 110 above may be applied equally to each of the plurality of memory blocks BLK1 to BLKz.

The control logic 120 may control the overall operation of various operations within the memory device 100. The control logic 120 may output various control signals in response to the command and the addresses received from the memory controller 200. For example, the control logic 120 may output a voltage control signal to perform an operation according to the command, a block address, a row address, and a column address corresponding to the address.

The page buffer unit 140 may include a plurality of page buffers PB1 to PBn. The plurality of page buffers PB1 to PBn may be connected to a string through the corresponding bitline BL. The page buffer unit 140 may select at least one bitline among the bitlines BL in response to a column address. The page buffer unit 140 may operate as a write driver or a sense amplifier, depending on its operation. For example, during a program operation, the page buffer unit 140 may change or maintain the threshold voltage of a select transistor or memory cell by applying a program allowance voltage or a program inhibit voltage to a selected bitline. During a read operation, the page buffer unit 140 may detect the current through the selected bitline and identify the threshold voltage status of the corresponding memory cell.

The voltage generator 150 may generate various types of voltages for performing program operations, read operations, etc. based on voltage control signals. For example, the voltage generator 150 may generate program voltage, program pass voltage, program voltage for verification, verification pass voltage, read voltage, read pass voltage, etc. to be applied to wordlines connected to each page.

The row decoder 160 may select at least one of a plurality of wordlines and a plurality of select lines in response to a row address. The row decoder 160 may deliver various voltages supplied from the voltage generator 150 to selected lines.

In some implementations, the control logic 120 may perform a program operation to adjust the threshold voltage of a select transistor. The select transistor may be selected by address. In some implementations, the control logic 120 may perform a program operation to store data in a memory cell. The memory cell may be selected by address.

A program operation may include a program pulse operation and a program verification operation. The program pulse operation may be an operation that increases the threshold voltage by injecting charge into a memory cell or select transistor by applying a program voltage to the wordline WL or a special wordline. The program verification operation may be an operation to identify whether the threshold voltage has reached the target value by applying voltage for verification to the wordline WL or a special wordline after the program pulse operation.

For example, the program pulse operation may include applying a program voltage (for example, 20V) to the wordline WL or special wordline selected by the row address, applying the program pass voltage (for example, 10V, etc.) to an unselected wordline WL and/or a special wordline by a row address, applying a program allowable voltage (for example, 0V) to a bitline selected by a column address, and applying a program inhibit voltage (for example, 10V) to an unselected bitline by a column address.

For example, the program verification operation may include applying a voltage for verification (for example, 2V, 3V, 5V, etc.) to the selected wordline WL or special wordline, applying a verification pass voltage (for example, 10V) to the unselected wordline WL and/or the special wordline, and identifying whether the threshold voltage has reached the target value based on the current flow of the bitline.

In some implementations, the control logic 120 may terminate a program operation when it is identified that the program is complete according to a program verification operation, and perform the next program operation when it is identified that the program is not complete. As such, the control logic 120 may repeatedly perform program operations based on the results of program verification operations. In some implementations, when the program is found to be incomplete, the control logic 120 may increase the level of the program voltage applied in the program pulse operation of the next program operation.

The control logic 120 may perform a read operation to identify the threshold voltage of the select transistor. For example, the read operation may include applying the read voltage (for example, 2V, 3V, 5V, etc.) to the selected special wordline, applying the read pass voltage (for example, 10V, etc.) to the unselected wordline WL and/or special wordline, and identifying the current flowing through the bitline to identify the threshold voltage of the select transistor.

According to some implementations of the present disclosure (e.g., the memory controllers, storage devices, and methods of operating the same described herein), the reliability of data storage may be increased. For example, deterioration of a select transistor may be prevented or reduced in advance. According to some implementations, a timepoint for performing program operations may be optimized by advancing or delaying the trigger time depending on the level of deterioration. According to some implementations, data loss due to deterioration of select transistor may be reduced. According to some implementations, the stability of memory blocks may be improved and the lifespan of memory blocks may be extended.

The electronic devices described above may include a processor, a memory for storing and executing program data, a permanent storage such as a disk drive, and/or a user interface device such as a communication port, a touch panel, a key and/or a button that communicates with an external device. Methods implemented as software modules or algorithms may be stored in a computer-readable recording medium as computer-readable codes or program instructions executable on the processor. Here, the computer-readable recording medium includes a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

Elements of the examples described above may be represented by functional block elements and various processing steps. The functional blocks may be implemented in any number of hardware and/or software configurations that perform specific functions. For example, disclosed operations and functionalities may correspond to integrated circuit configurations, such as memory, processing, logic and/or look-up table, that may execute various functions by the control of one or more microprocessors or other control devices. Disclosed operations and functionalities may be implemented as software programming or software elements. For example, elements of the foregoing examples may be implemented in a programming or scripting language such as C, C++, Java, assembler, etc., including various algorithms implemented as a combination of data structures, processes, routines, or other programming constructs. Functional aspects may be implemented in an algorithm running on one or more processors. Terms such as “mechanism,” “element,” “means” and “configuration” may be used broadly and are not limited to mechanical and physical elements. The terms may include the meaning of a series of routines of software in association with a processor or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples thereof, it will be apparent to those of ordinary skill in the art that various changes and modifications may be made thereto without departing from the spirit and scope of the present disclosure as set forth in the following claims.

What is claimed is:

1. A storage device comprising:
a memory device comprising a memory block, wherein the memory block comprises a select transistor group connected to a special wordline; and
a memory controller configured to:
identify a trigger time corresponding to the select transistor group, wherein the trigger time is based on a degradation level of the select transistor group; and
based on the trigger time elapsing, control the memory device to perform a program operation, wherein the program operation comprises adjusting a threshold voltage of at least one of a plurality of select transistors included in the select transistor group.

2. The storage device of claim 1, wherein the memory controller is configured to:
control the memory device to perform a read operation, wherein the read operation comprises applying a read voltage to the special wordline;
based on the read operation, determine a number of failed select transistors among the plurality of select transistors included in the select transistor group, wherein the failed select transistors have a threshold voltage lower than the read voltage; and
determine the degradation level based on the number of failed select transistors among the plurality of select transistors.

3. The storage device of claim 2, wherein the degradation level is based on a ratio of the number of the failed select transistors to a number of the plurality of select transistors.

4. The storage device of claim 2, wherein the memory controller is configured to identify the trigger time based on mapping information, and
wherein the mapping information indicates a correlation in which trigger times decrease as degradation levels increase.

5. The storage device of claim 4, wherein the memory controller comprises a buffer memory configured to store the trigger time corresponding to the select transistor group.

6. The storage device of claim 2, wherein the read voltage is greater than a first voltage configured to deactivate the select transistor group, and wherein the read voltage is less than a second voltage configured to activate the select transistor group.

7. The storage device of claim 6, wherein the read voltage is less than or equal to a verification voltage that the memory device is configured to apply during a program verification operation for the select transistor group.

8. The storage device of claim 6, wherein the read operation comprises:
applying, to the special wordline, a first sub-read voltage greater than the first voltage; and
applying, to the special wordline, a second sub-read voltage greater than the first sub-read voltage and less than the second voltage, and
wherein the memory controller is configured to determine the degradation level based on a weighted sum, and wherein the memory controller is configured to determine the weighted sum by:
applying a first weight value to a first number of first select transistors among the plurality of select transistors, the first select transistors having a threshold voltage smaller than the first sub-read voltage; and
applying a second weight value to a second number of second select transistors among the plurality of select transistors, the second select transistors having a threshold voltage equal to or greater than the first sub-read voltage and less than the second sub-read voltage, wherein the second weight value is smaller than the first weight value.

9. The storage device of claim 2, wherein the memory controller is configured to control the memory device to perform the read operation based on an interval of time elapsing from a timepoint at which a data-related operation for the memory block is completed, and wherein the interval of time is an arbitrary variable time or a preset fixed time.

10. The storage device of claim 1, wherein the program operation comprises:
applying a program voltage to the special wordline;
applying a program allowance voltage to a bitline connected to a select transistor, among the plurality of select transistors, having a threshold voltage lower than a voltage for verification; and
applying a program inhibit voltage to a bitline connected to a select transistor, among the plurality of select transistors, having a threshold voltage higher than the voltage for verification.

11. The storage device of claim 1, wherein the memory controller is configured to, based on the trigger time elapsing, transmit, to the memory device, (i) a program command to control the program operation to be performed and (ii) an address corresponding to the select transistor group.

12. A method of operating a storage device comprising a memory block, wherein the memory block comprises a select transistor group connected to a special wordline, the method comprising:
identifying a trigger time corresponding to the select transistor group, wherein the trigger time is based on a degradation level of the select transistor group; and
based on the trigger time elapsing, performing a program operation to adjust a threshold voltage of at least one of a plurality of select transistors included in the select transistor group.

13. The method of claim 12, further comprising:
performing a read operation to apply a read voltage to the special wordline;
based on the read operation, determining a number of failed select transistors among the plurality of select transistors included in the select transistor group, wherein the failed select transistors have a threshold voltage lower than the read voltage; and
determining the degradation level based on the number of failed select transistors among the plurality of select transistors.

14. The method of claim 13, wherein the degradation level is based on a ratio of the number of the failed select transistors to a number of the plurality of select transistors.

15. The method of claim 13, wherein identifying the trigger time comprises identifying the trigger time based on mapping information, and
wherein the mapping information indicates a correlation in which trigger times decrease as degradation levels increase.

16. The method of claim 13, wherein the read voltage is greater than a first voltage configured to deactivate the select transistor group, and the read voltage is less than a second voltage configured to activate the select transistor group.

17. The method of claim 16, wherein performing the read operation comprises:
applying, to the special wordline, a first sub-read voltage greater than the first voltage; and
applying, to the special wordline, a second sub-read voltage greater than the first sub-read voltage and less than the second voltage, and
wherein the method comprises determining the degradation level based on a weighted sum, and wherein the method comprises determining the weighted sum by:
applying a first weight value to a first number of first select transistors among the plurality of select transistors, the first select transistors having a threshold voltage smaller than the first sub-read voltage; and
applying a second weight value to a second number of second select transistors among the plurality of select transistors, the second select transistors having a threshold voltage equal to or greater than the first sub-read voltage and less than the second sub-read voltage.

18. The method of claim 13, wherein performing the read operation is performed based on an interval of time elapsing from a timepoint at which a data-related operation for the memory block is completed, and
wherein the interval of time is an arbitrary variable time or a preset fixed time.

19. A memory controller comprising:
a buffer memory configured to store information; and
a processor configured to:
store a trigger time in the buffer memory, wherein the trigger time is based on a degradation level for a select transistor group of a memory block included in a memory device; and
based on the trigger time elapsing, control the memory device to perform a program operation, wherein the program operation comprises adjusting a threshold voltage of at least one of a plurality of select transistors included in the select transistor group.

20. The memory controller of claim 19, wherein the processor is configured to:
control the memory device to perform a read operation, wherein the read operation comprises applying a read voltage to a special wordline connected to the select transistor group;
based on the read operation, determine a number of failed select transistors among the plurality of select transistors included in the select transistor group, wherein the failed select transistors have a threshold voltage lower than the read voltage; and
determine the degradation level based on the number of failed select transistors among the plurality of select transistors.
